(19) United States
(12) Patent Application Publication
(10) Pub. No.: US 2016/0240549 A1
(43) Pub. Date: Aug. 18, 2016

(54) Method For Manufacturing Semiconductor Device

(71) Applicant: Kabushiki Kaisha Toshiba, Tokyo (JP)

(72) Inventor: Mitsuhiro OMURA, Kuwana (JP)

(73) Assignee: Kabushiki Kaisha Toshiba

(21) Appl. No.: 14/740,901

(22) Filed: Jun. 16, 2015

Related U.S. Application Data
(60) Provisional application No. 62/117,551, filed on Feb. 18, 2015.

(51) Int. Cl. H01L 27/115

(52) U.S. Cl. CPC H01L 27/11568; H01L 27/11582

(57) ABSTRACT

According to one embodiment, a method for manufacturing a semiconductor device includes forming a first film on a multilayer body including two or more stacked films. One stacked film includes a first layer and a second layer. The first film includes a plurality of regions different in aperture ratio. The method includes forming a mask layer by forming a second film on the first film and in apertures formed in the first film. The mask layer is thicker in a region in which the aperture ratio is lower. The mask layer has a multilevel upper surface. The method includes eliminating a thinnest portion of the mask layer to expose part of the multilayer body by etching back the multilevel upper surface. The method includes etching one stacked film on a surface side of an exposed region of the multilayer body in a stacking direction.

### CROSS-REFERENCE TO RELATED APPLICATION

This application is based upon and claims the benefit of priority from U.S. Provisional Patent Application 62/117,551, filed on Feb. 18, 2015; the entire contents of which are incorporated herein by reference.

### FIELD

Embodiments described herein relate generally to a method for manufacturing a semiconductor device.

### BACKGROUND

A memory device of a three-dimensional structure including a multilayer body has been proposed. A plurality of electrode layers are stacked in the multilayer body. A charge storage film and a semiconductor film are provided so as to extend in the stacking direction of the multilayer body.

Each of the plurality of electrode layers in such a three-dimensional memory device is connected to a control circuit by a contact structure. In a proposed contact structure, the plurality of electrode layers are processed into a staircase pattern.

A proposed method for processing the electrode layers into a staircase pattern is to alternately repeat slimming a resist film and etching part of the multilayer body including the electrode layers. However, with the increase of the number of electrode layers and the increase of the number of stairs in the staircase part of the electrode layers, the resist film may disappear while slimming of the resist film is repeated a plurality of times. Thickening the film thickness of the resist film is restricted by the resolution limit of lithography.

### BRIEF DESCRIPTION OF THE DRAWINGS

FIG. 1 is a schematic perspective view of a memory cell array of a semiconductor device of an embodiment;

FIG. 2 is a schematic sectional view of a memory cell of the semiconductor device of the embodiment;

FIG. 3 is a schematic sectional view of a staircase-shaped contact part of the semiconductor device of the embodiment; and

FIGS. 4A to 23 are schematic sectional views showing a method for manufacturing the semiconductor device of the embodiment.

### DETAILED DESCRIPTION

According to one embodiment, a method for manufacturing a semiconductor device includes forming a first film on a multilayer body including two or more stacked films. One stacked film includes a first layer and a second layer made of a material different from a material of the first layer. The first film includes a plurality of regions different in aperture ratio and is made of a material different from a material of the stacked films. The method includes forming a mask layer by forming a second film on the first film and in apertures formed in the first film. The second film is made of a material different from the material of the stacked films. The mask layer is thicker in a region in which the aperture ratio is lower. The mask layer has a multilevel upper surface. The method includes eliminating a thinnest portion of the mask layer to expose part of the multilayer body by etching back the multilevel upper surface in a thickness direction of the mask layer. The method includes etching one stacked film on a surface side of an exposed region of the multilayer body in a stacking direction.

Embodiments will now be described with reference to the drawings. In the drawings, like elements are labeled with like reference numerals.

In the embodiments, a semiconductor memory device including a memory cell array of a three-dimensional structure is described as an example of the semiconductor device.

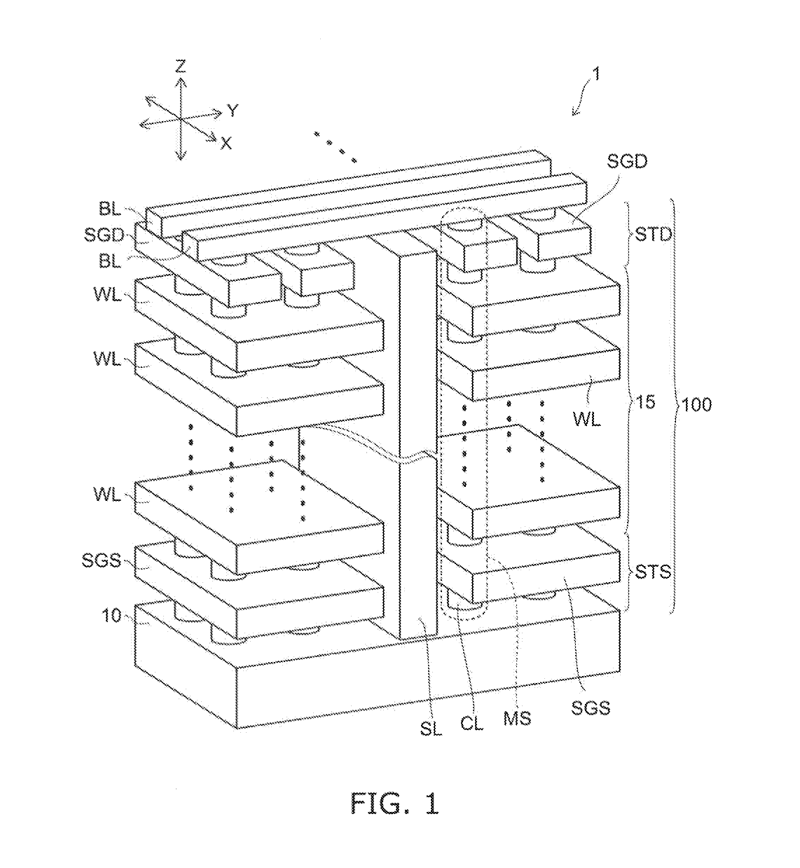

FIG. 1 is a schematic perspective view of a memory cell array 1 of an embodiment. In FIG. 1, for clarity of illustration, insulating layers are not shown.

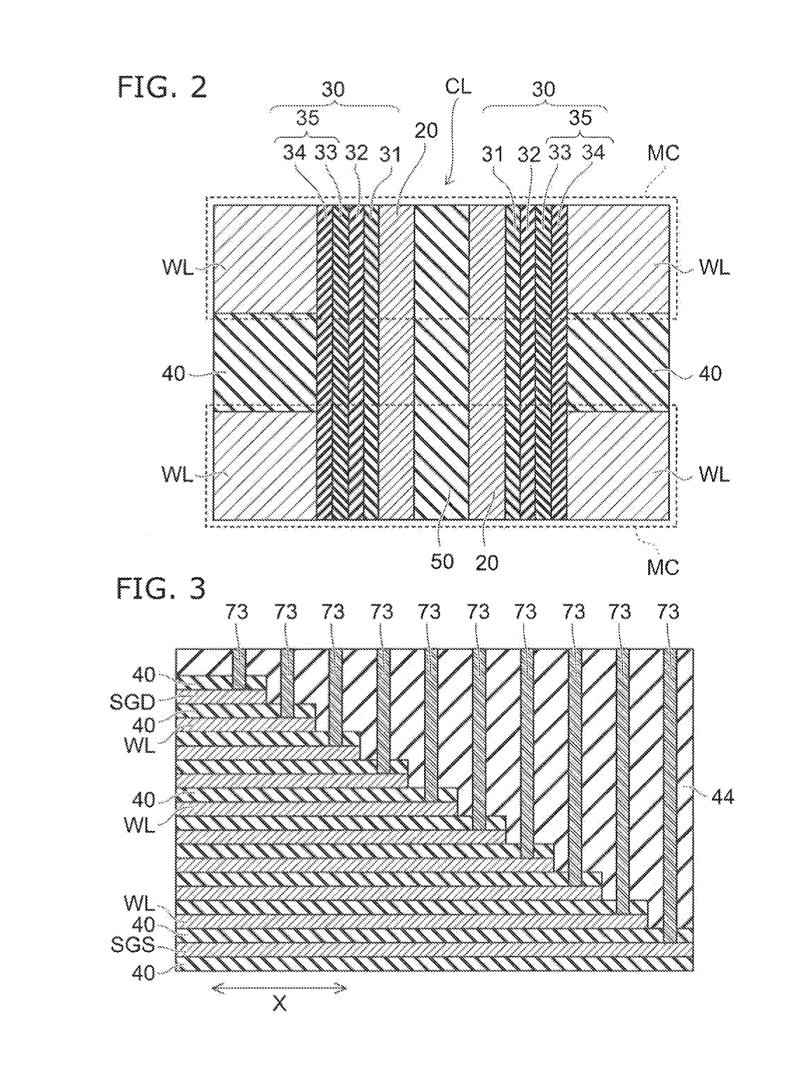

FIG. 2 is a schematic sectional view of a memory cell MC of the embodiment.

In FIG. 1, two directions parallel to the major surface of the substrate 10 and orthogonal to each other are referred to as X-direction (first direction) and Y-direction (second direction). The direction orthogonal to both the X-direction and the Y-direction is referred to as Z-direction (third direction or stacking direction).

A source side select gate (lower gate layer) SGS is provided on the substrate 10 via an insulating layer. A multilayer body 15 is provided on the source side select gate SGS. Electrode layers WL and insulating layers are alternately stacked in the multilayer body 15. The multilayer body 15 includes a plurality of electrode layers WL and a plurality of Insulating layers. As shown in FIG. 2, an insulating layer 40 is provided between the electrode layers WL. A drain side select gate (upper gate layer) SGD is provided on the uppermost electrode layer WL via an insulating layer.

The source side select gate SGS, the drain side select gate SGD, and the electrode layer WL are metal layers. The source side select gate SGS, the drain side select gate SGD, and the electrode layer WL are e.g. layers primarily including tungsten. Alternatively, the source side select gate SGS, the drain side select gate SGD, and the electrode layer WL are e.g. silicon layers composed primarily of silicon. The silicon layer is doped with e.g. boron as an impurity for imparting conductivity. Alternatively, the source side select gate SGS, the drain side select gate SGD, and the electrode layer WL may include metal silicide.

A plurality of bit lines BL (e.g., metal films) are provided on the drain side select gate SGD via an Insulating layer.

A plurality of drain side select gates SGD are separated into a plurality in the Y-direction, each corresponding to the row of a plurality of columnar parts CL arranged in the X-direction. Each drain side select gate SGD extends in the X-direction.

The bit lines BL are separated into a plurality in the X-direction, each corresponding to the row of a plurality of columnar parts CL arranged in the Y-direction. Each bit line BL extends in the Y-direction.

A plurality of columnar parts CL penetrate through the multilayer body 100 including the source side select gate SGS, the multilayer body 15 including a plurality of electrode layers WL, and the drain side select gate SGD. The columnar part CL extends in the stacking direction (Z-direction) of the multilayer body 15. The columnar part CL is formed like e.g. a circular cylinder or an elliptic cylinder.

The multilayer body 100 is separated into a plurality in the Y-direction. A source layer SL, for instance, is provided in the separating part.

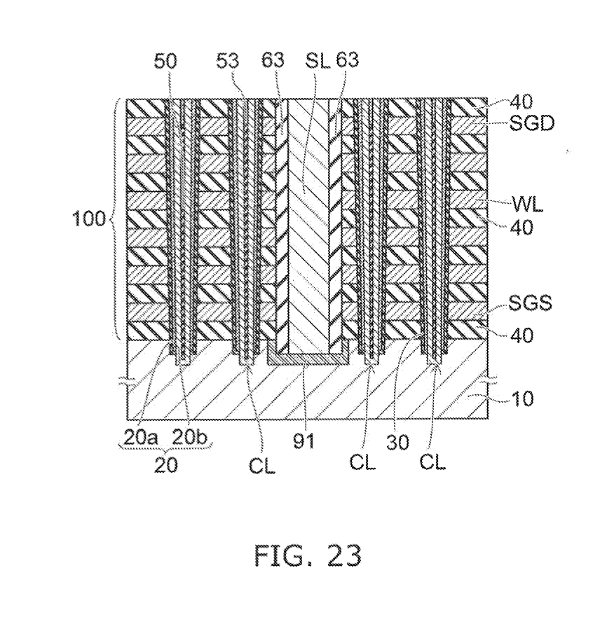

The source layer SL includes a metal (e.g., tungsten). The lower end of the source layer SL is connected to the substrate 10. The upper end of the source layer SL is connected to an upper interconnection, not shown. An insulating film 63 is provided between the source layer SL and the electrode layer WL, between the source layer SL and the source side select gate SGS, and between the source layer SL and the drain side select gate SGD as shown in FIG. 23 described later.

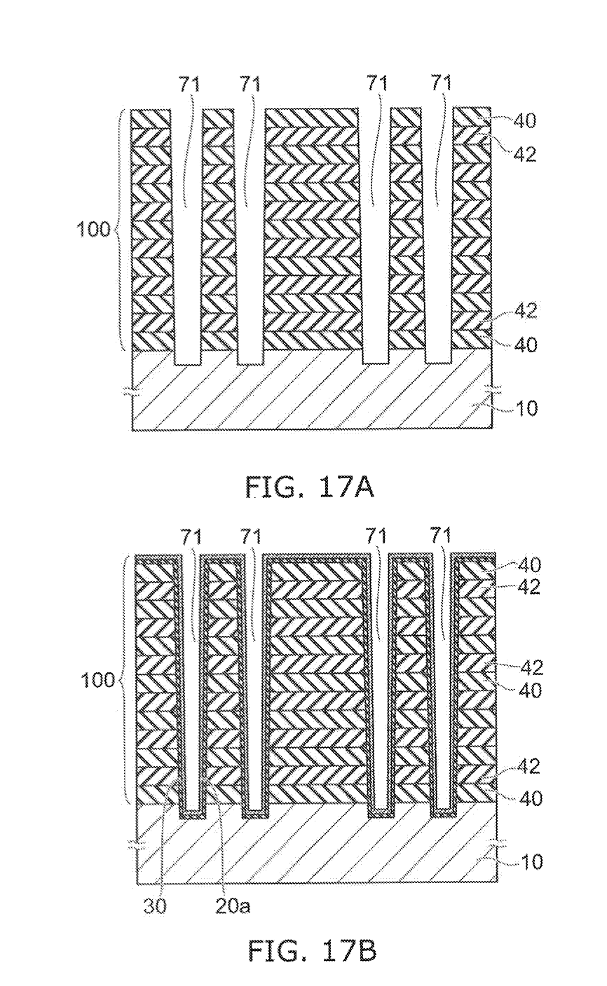

The columnar part CL is formed in a memory hole 71 (shown in FIG. 17A) formed in the multilayer body 100. A semiconductor film (semiconductor body) 20 shown in FIG. 2 is provided in the memory hole 71. The semiconductor film 20 is e.g. a silicon film composed primarily of silicon. The semiconductor film 20 includes substantially no impurity.

The semiconductor film 20 is formed like a pipe extending in the stacking direction of the multilayer body 100. The upper end part of the semiconductor film 20 penetrates through the drain side select gate SGD and is connected to the bit line BL shown in FIG. 1.

The lower end part of the semiconductor film 20 penetrates through the source side select gate SGS and is connected to the substrate 10. The lower end part of the semiconductor film 20 is electrically connected to the source layer SL through the substrate 10.

As shown in FIG. 2, a memory film 30 is provided between the sidewall of the memory hole and the semiconductor film 20. The memory film 30 includes a block insulating film 35, a charge storage film 32, and a tunnel insulating film 31. The memory film 30 is formed like a pipe extending in the stacking direction of the multilayer body 100.

The block insulating film 35, the charge storage film 32, and the tunnel insulating film 31 are provided sequentially from the electrode layer WL side between the electrode layer WL and the semiconductor film 20. The block insulating film 35 is in contact with the electrode layer WL. The tunnel insulating film 31 is in contact with the semiconductor film 20. The charge storage film 32 is provided between the block insulating film 35 and the tunnel insulating film 31.

The memory film 30 surrounds the outer periphery of the semiconductor film 20. The electrode layer WL surrounds the outer periphery of the semiconductor film 20 via the memory film 30. A core insulating film 50 is provided inside the semiconductor film 20.

The electrode layer WL functions as a control gate of the memory cell MC. The charge storage film 32 functions as a data storage layer for storing charge injected from the semiconductor film 20. A memory cell MC is formed in the crossing portion of the semiconductor film 20 and each electrode layer WL. The memory cell MC has a vertical transistor structure in which the semiconductor film 20 is surrounded with the control gate.

The semiconductor device of the embodiment is a nonvolatile semiconductor memory device capable of electrically and freely erasing/writing data and retaining its memory content even when powered off.

The memory cell MC is e.g. a charge trap type memory cell. The charge storage film 32 includes a large number of trap sites for trapping charge, and includes e.g. a silicon nitride film.

The tunnel insulating film 31 serves as a potential barrier when charge is injected from the semiconductor film 20 into the charge storage film 32, or when the charge stored in the charge storage film 32 is diffused into the semiconductor film 20. The tunnel insulating film 31 includes e.g. a silicon oxide film. The tunnel insulating film 31 may be a stacked film of a structure in which a silicon nitride film is sandwiched between a pair of silicon oxide films (ONO film). The tunnel insulating film 31 made of an ONO film enables erase operation at a lower electric field than a monolayer silicon oxide film.

The block insulating film 35 prevents the charge stored in the charge storage film 32 from diffusing into the electrode layer WL. The block insulating film 35 includes a cap film 34 provided in contact with the electrode layer WL, and a block film 33 provided between the cap film 34 and the charge storage film 32.

The block film 33 is e.g. a silicon oxide film. The cap film 34 is a film having higher dielectric constant than silicon oxide film. The cap film 34 is e.g. a silicon nitride film, aluminum oxide film, hafnium oxide film, or yttrium oxide film. Such a cap film 34 provided in contact with the electrode layer WL can suppress back tunneling electrons injected from the electrode layer WL at erasure time.

As shown in FIG. 1, a drain side select transistor STD is provided in the upper end part of the columnar part CL. A source side select transistor STS is provided in the lower part of the columnar part CL.

The memory cell MC, the drain side select transistor STD, and the source side select transistor STS are vertical transistors in which the current flows in the stacking direction (Z-direction) of the multilayer body 100.

The drain side select gate SGD functions as a gate electrode (control gate) of the drain side select transistor STD. An insulating film functioning as a gate insulating film of the drain side select transistor STD is provided between the drain side select gate SGD and the semiconductor film 20.

The source side select gate SGS functions as a gate electrode (control gate) of the source side select transistor STS. An insulating film functioning as a gate insulating film of the source side select transistor STS is provided between the source side select gate SGS and the semiconductor film 20.

A plurality of memory cells MC with the respective electrode layers WL serving as control gates are provided between the drain side select transistor STD and the source side select transistor STS. The plurality of memory cells MC, the drain side select transistor STD, and the source side select transistor STS are series connected through the semiconductor film 20 to constitute one memory string MS. This memory string MS is arranged in a plurality in the X-direction and the Y-direction. Thus, a plurality of memory cells MC are provided three-dimensionally in the X-direction, the Y-direction, and the Z-direction.

FIG. 3 is a schematic sectional view of the staircase-shaped contact part of the semiconductor device of the embodiment.

Part of the multilayer body 100 including the source side select gate SGS, the drain side select gate SGD, and a plurality of electrode layers WL is processed into a staircase pattern as shown in FIG. 3. The X-direction shown in FIG. 3 corresponds to the X-direction shown in FIG. 1.

The source side select gate SGS, the drain side select gate SGD, and the electrode layers WL are processed into a staircase pattern along the X-direction. For instance, the source side select gate SGS is located in the lowermost stair of the staircase part. The drain side select gate SGD is located in the uppermost stair of the staircase part.

An insulating layer 40 is provided on each stair part of the source side select gate SGS, the drain side select gate SGD, and the electrode layer WL. The insulating layers 40 are also processed into a staircase pattern along the X-direction.

An interlayer insulating film 44 is provided on the staircase part. The interlayer insulating film 44 covers the staircase part. A plurality of vias (plugs) 73 are provided on the staircase part. The via 73 penetrates through the interlayer insulating film 44 and the insulating layer 40 of each stair. The vias 73 reach the source side select gate SGS, the drain side select gate SGD, and the electrode layers WL of the respective stairs.

The via 73 is formed from a conductive film including a metal. The vias 73 are electrically connected to the source side select gate SGS, the drain side select gate SGD, and the electrode layers WL of the respective stairs. Each via 73 is connected to an upper interconnection, not shown, provided on the multilayer body 100.

The source side select gate SGS, the drain side select gate SGD, and the electrode layer WL of the staircase-shaped contact part are integrally connected to the source side select gate SGS, the drain side select gate SGD, and the electrode layer WL of the memory cell array 1, respectively.

Thus, each of the source side select gate SGS, the drain side select gate SGD, and the electrode layer WL of the memory cell array 1 is connected to the upper interconnection through the via 73 of the staircase-shaped contact part. The upper interconnection is connected to e.g. a control circuit formed on the surface of the substrate 10. The control circuit controls the operation of the memory cell array 1.

A proposed method for processing a plurality of electrode layers WL into a staircase pattern is to repeat slimming and etching a plurality of times. The slimming step reduces the planar size of a resist film. The etching step etches one insulating layer 40 and one electrode layer WL using the resist film as a mask. The resist film is isotropically etched. The film thickness of the resist film also decreases with the reduction of the planar size.

Currently, the film thickness of the resist film is restricted to approximately several μm by the resolution limit of lithography. On the other hand, the width of the terrace portion of each stair of the staircase part (the X-direction width in FIG. 3), i.e., the setback amount (slimming amount) of the resist film per one time, is approximately several hundred nm to 1 μm. With the increase of the number of stacked electrode layers WL and the increase of the number of times of slimming the resist film, the resist film may disappear before completing staircase processing for all the electrode layers WL.

A possible method for solving this problem may be considered as follows. During the staircase processing, the thin residual resist film is once removed by ashing. The staircase processing part is further subjected to chemical treatment. Then, a resist film is applied again and patterned by lithography. Furthermore, slimming the resist film and etching the stacked film are similarly repeated.

However, the number of cycles of removing the residual resist film, chemical treatment, and patterning the new resist film increases with the increase of the number of stairs of the electrode layers WL. This incurs a significant increase of the number of process steps and Increase of cost.

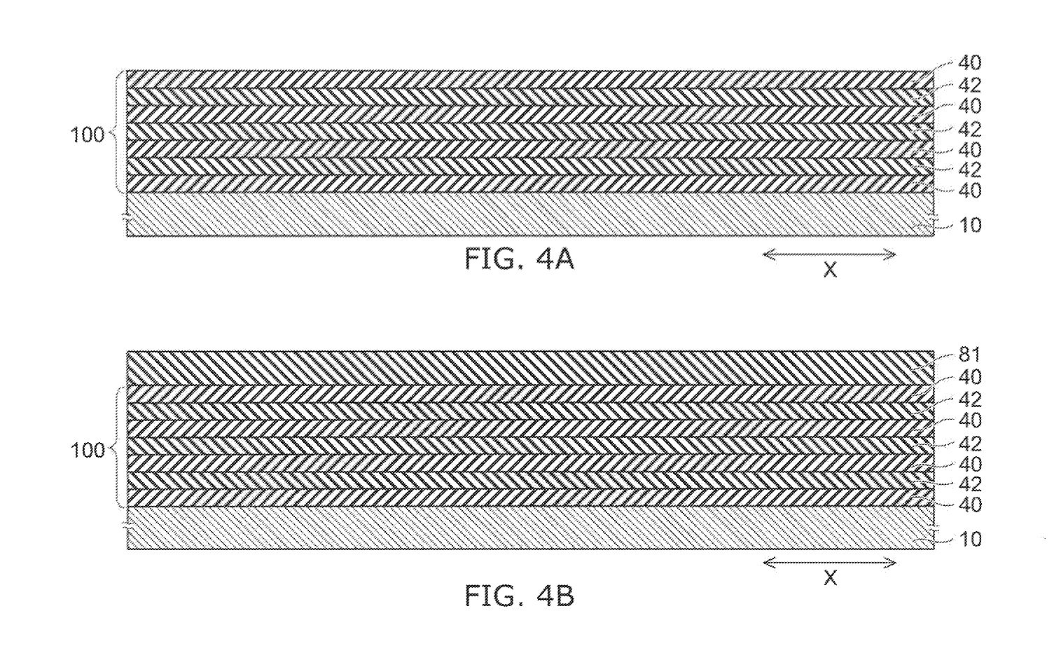

FIGS. 4A to 9B are schematic sectional views showing a method for forming a staircase-shaped contact part in the semiconductor device of the embodiment.

FIGS. 4A to 9B are schematic sectional views of the region in which the staircase-shaped contact part shown in FIG. 3 is formed in the multilayer body 100. The X-direction shown in FIGS. 4A to 9B corresponds to the X-direction shown in FIG. 3.

As shown in FIG. 4A, on a substrate 10, a multilayer body 100 is formed as a target of staircase processing. The multilayer body 100 includes a plurality of sacrificial layers (first layers) 42 and a plurality of Insulating layers (second layers) 40. The substrate 10 is e.g. a semiconductor substrate such as a silicon substrate.

The insulating layers 40 and the sacrificial layers 42 are alternately formed on the substrate 10. Two or more stacked films are formed on the substrate 10. One stacked film includes one insulating layer 40 and one sacrificial layer 42. The insulating layer 40 and the sacrificial layer 42 are made of heterogeneous material each other. The number of stacked layers of the sacrificial layers 42 and the insulating layers 40 is not limited to the number of layers shown in the figure.

The insulating layer 40 is e.g. a silicon oxide film. The sacrificial layer 42 is made of a material different from the insulating layer 40. The sacrificial layer 42 is e.g. a silicon nitride film. The sacrificial layers 42 will be replaced by conductive layers constituting select gates SGS, SGD and electrode layers WL in a later step.

As shown in FIG. 48, a first film 81 is formed on the multilayer body 100. The first film 81 includes a photosensitizing agent. The first film 81 is a photosensitive resist film.

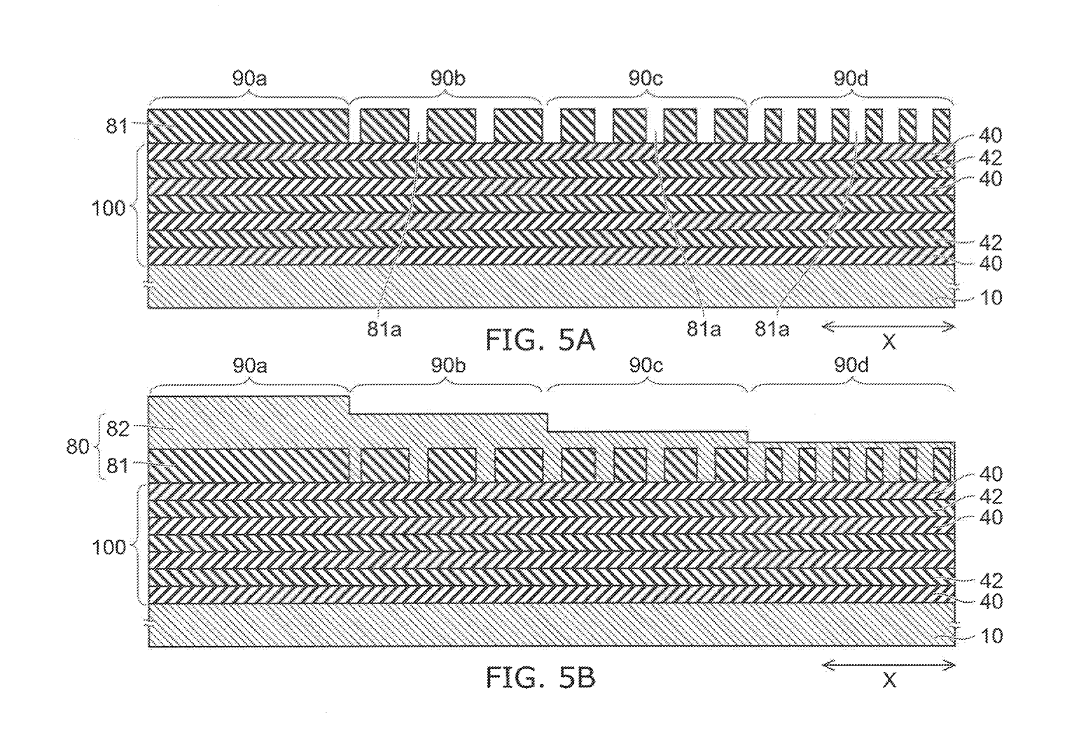

The first film 81 is patterned by light exposure and development on the first film 81. As shown in FIG. 5A, a plurality of apertures 81a are formed in the first film 81. The bottom of the aperture 81a reaches the upper surface of the multilayer body 100. The aperture 81a is a hole. Alternatively, the aperture 81a is a slit extending in the direction traversing the page (Y-direction in FIG. 1).

The first film 81 includes a plurality of regions 90a-90d. The plurality of regions 90a-90d are arranged along the X-direction. The X-direction widths of the plurality of regions 90a-90d are generally equal. The Y-direction widths of the plurality of regions 90a-90d are generally equal. That is, the areas of the plurality of regions 90a-90d are generally equal.

The plurality of regions 90a-90d are different in aperture ratio. The aperture ratio represents the proportion of the area of the apertures 81a to the area of each region 90a-90d. Conversely, the plurality of regions 90a-90d are different in the coverage ratio of the first film 81. The coverage ratio represents the proportion of the area of the upper surface of the multilayer body 100 covered with the first film 81 to the area of each region 90a-90d.

For instance, no aperture is formed in the region 90a. Thus, the aperture ratio of the region 90a is 0%. For instance, the aperture ratio of the region 90b is 10%. The aperture ratio of the region 90c is 30%. The aperture ratio of the region 90d is 50%.

The plurality of regions 90a-90d are arranged along the X-direction in the increasing order of aperture ratio from the region 90a of the lowest aperture ratio toward the region 90d of the highest aperture ratio.

As shown in FIG. 5B, a second film 82 is formed on the first film 81. The second film 82 is formed also in the aperture 81a. The second film 82 is a non-photosensitive organic film. The second film 82 is supplied onto the first film 81 and into the aperture 81a in a liquid state having fluidity. Then, the second film 82 is thermally cured. The second film 82 is cured by heat treatment below the heatproof temperature of the first film 81 made of e.g. a resist film.

The second film 82 is applied uniformly onto the first film 81. The film thickness (height) of the first film 81 is generally equal over the plurality of regions 90a-90d. Thus, the total amount (total volume) of the second film 82 formed in the aperture 81a is different among the regions 90a-90d depending on the difference in the aperture ratio of the first film 81. This causes difference in the thickness (height) of the second film 82 on the first film 81 among the regions 90a-90d.

The thickness of the second film 82 on the first film 81 in the region 90a of the lowest aperture ratio is thicker than the thickness of the second film 82 on the first film 81 in the region 90b having higher aperture ratio than the region 90a.

The thickness of the second film 82 on the first film 81 in the region 90c having higher aperture ratio than the region 90b is thinner than the thickness of the second film 82 on the first film 81 in the region 90b.

The thickness of the second film 82 on the first film 81 in the region 90d having higher aperture ratio than the region 90c is thinner than the thickness of the second film 82 on the first film 81 in the region 90c.

The thickness of the second film 82 on the first film 81 is thinned stepwise along the X-direction from the region 90a of the lowest aperture ratio toward the region 90d of the highest aperture ratio.

The first film 81 and the second film 82 are homogeneous films made of an organic-based material. The material is different from the sacrificial layer (silicon nitride film) 42 and the insulating layer (silicon oxide film) 40 of the multilayer body 100. The first film 81 and the second film 82 form a mask layer 80 for processing the multilayer body 100 into a staircase pattern. The mask layer 80 of the organic-based material has etching selectivity with respect to the multilayer body 100 including the sacrificial layer (silicon nitride film) 42 and the insulating layer (silicon oxide film) 40.

The total thickness of the mask layer 80 is thicker in the region having a lower aperture ratio of the first film 81. The thickness of the mask layer 80 is thinned stepwise along the X-direction from the region 90a of the lowest aperture ratio toward the region 90d of the highest aperture ratio. Thus, the upper surface of the mask layer 80 is formed in a staircase pattern along the X-direction.

In the example shown in FIG. 5B, the thickness of the second film 82 on the first film 81 is steeply changed at the boundary between the regions 90a-90d. However, the thickness may be changed gradually.

Next, the multilevel upper surface of the mask layer 80 is etched back and set back in the thickness direction of the mask layer 80. For instance, the mask layer 80 of the organic-based material is etched back by reactive ion etching (RIE) technique using an oxygen-containing gas. At the time of this etch-back, the etching rate of the first film 81 is generally equal to the etching rate of the second film 82. Thus, the setback amount of the first film 81 is generally equal to the setback amount of the second film 82. Accordingly, the multilevel upper surface is reflected also on the upper surface of the remaining mask layer 80.

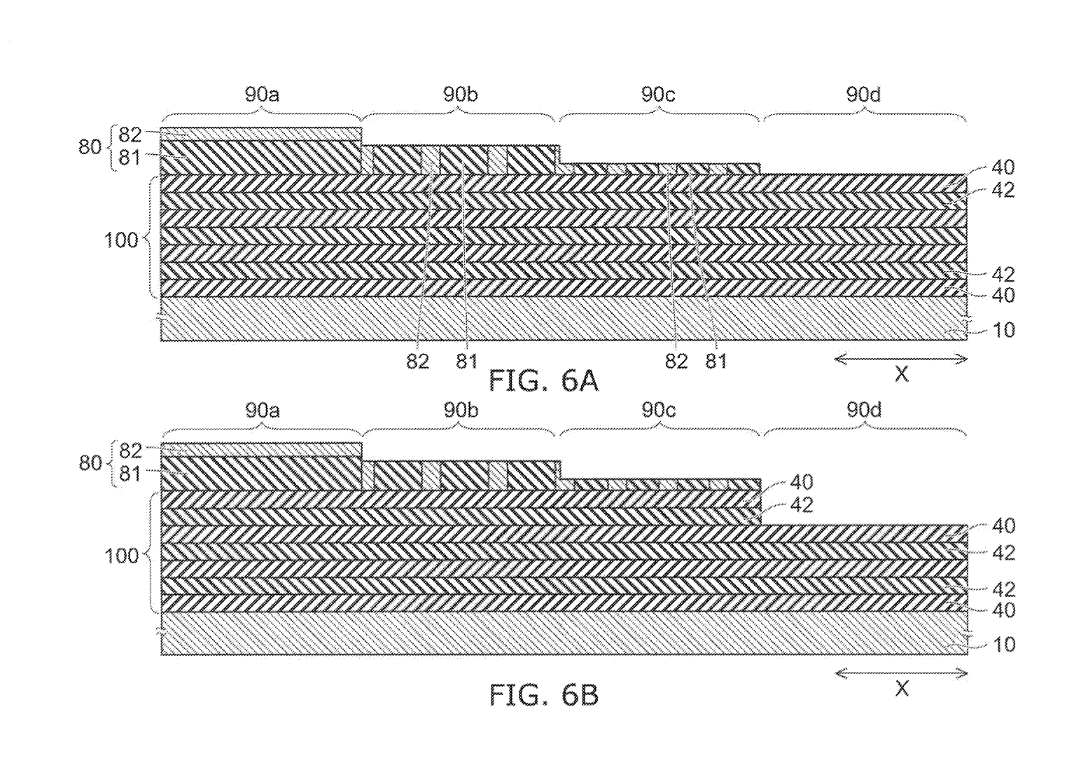

The mask layer 80 is etched back until the thinnest portion of the mask layer 80 (the mask layer 80 in the region 90d) disappears. As shown in FIG. 6A, part of the multilayer body 100 is exposed by disappearance of the mask layer 80 in the region 90d. The thickness of the mask layer 80 in the other regions 90a-90c is made thinner than the thickness before etch-back shown in FIG. 5B.

In this state, the exposed region 90d of the multilayer body 100 is etched in the stacking direction by RIE technique using e.g. a fluorocarbon-based gas. The reference numerals 90a-90d representing the regions of the first film 81 are hereinafter used also as reference numerals representing the exposed regions of the multilayer body 100 for convenience of description.

One stacked film (one insulating layer 40 and one sacrificial layer 42) at the surface of the exposed region 90d of the multilayer body 100 is etched and removed as shown in FIG. 6B.

By removal of the one stacked film, as shown in FIG. 6B, a step difference is formed in the multilayer body 100 between the surface covered with the mask layer 80 and the exposed surface.

Subsequently, the step of etching back the remaining mask layer 80 to eliminate the thinnest portion and the step of etching one stacked film in the exposed region of the multilayer body 100 are repeated a plurality of times.

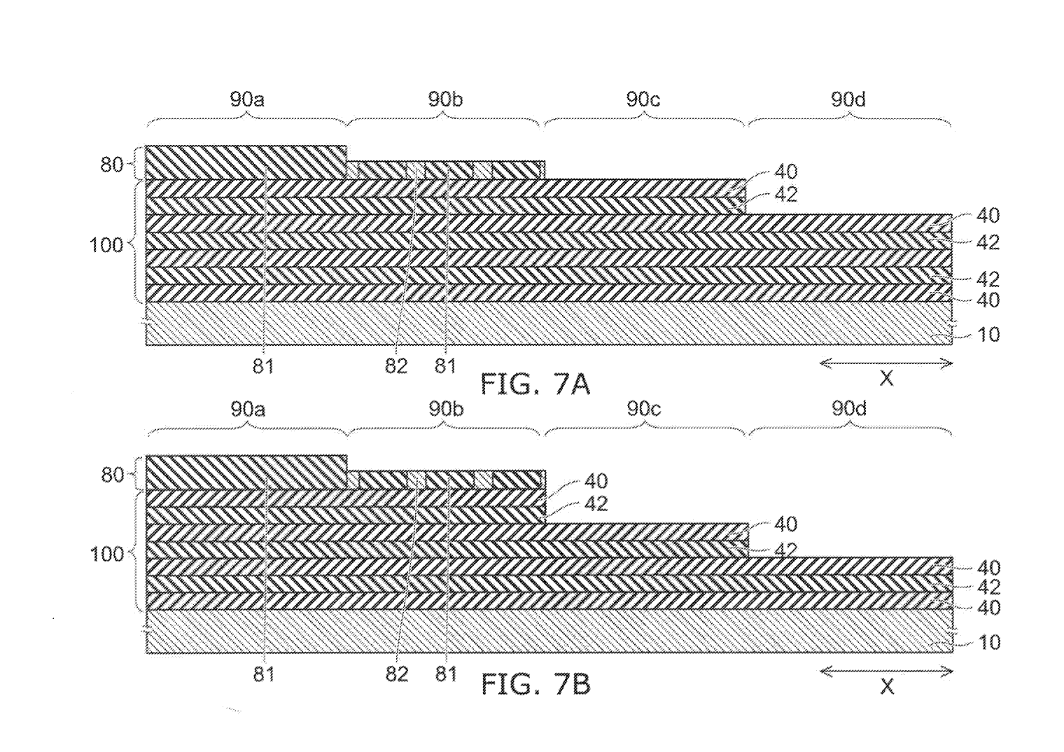

More specifically, the multilevel upper surface of the remaining mask layer 80 in FIG. 6B is etched back. Thus, the mask layer 80 is set back in the thickness direction. The thinnest portion of the remaining mask layer 80 (the mask layer 80 in the region 90c) disappears by this etch-back. Thus, the multilayer body 100 in the region 90c is exposed as shown in FIG. 7A.

Then, one stacked film (one insulating layer 40 and one sacrificial layer 42) at the surface of the exposed regions 90c-90d of the multilayer body 100 is etched and removed as shown in FIG. 7B by RIE technique using the mask layer 80 remaining in the regions 90a-90b as a mask.

One stacked film (one insulating layer 40 and one sacrificial layer 42) at the surface of the region 90d and the newly exposed region 90c is removed. In the region 90d, one stacked film (one insulating layer 40 and one sacrificial layer 42) was already removed in the previous step. Thus, the number of stairs is increased.

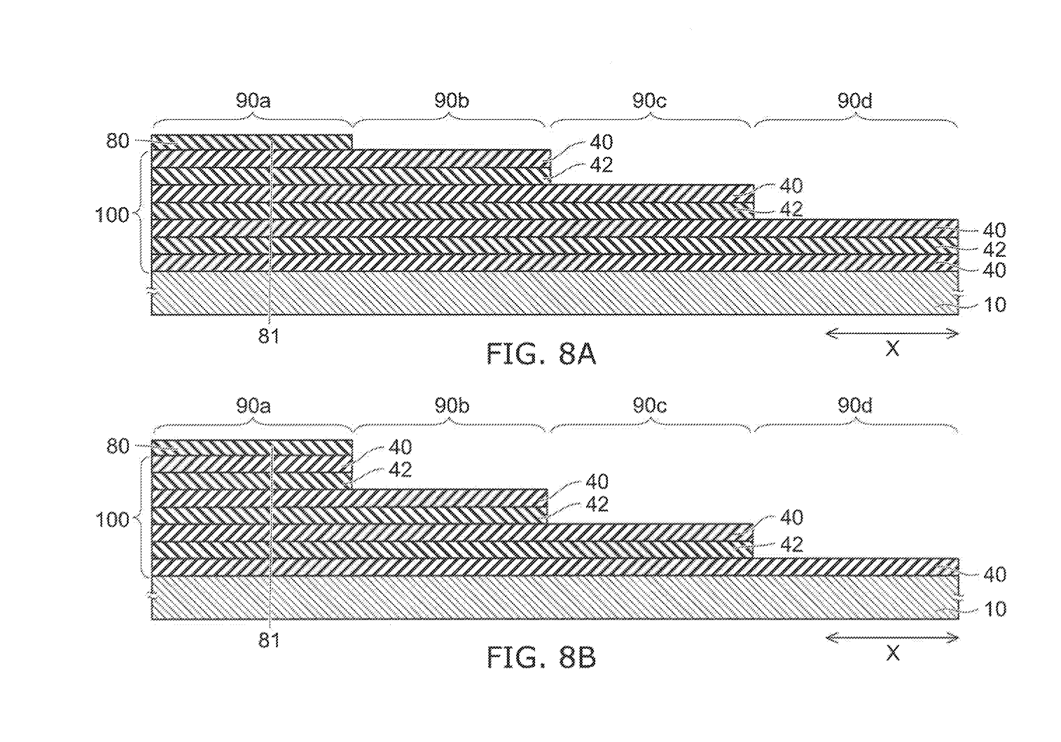

Subsequently, likewise, the multilevel upper surface of the remaining mask layer 80 in FIG. 7B is etched back. Thus, the mask layer 80 is set back in the thickness direction. The thinnest portion of the remaining mask layer 80 (the mask layer 80 in the region 90b) disappears by this etch-back. Thus, the multilayer body 100 in the region 90b is exposed as shown in FIG. 8A.

Then, one stacked film (one insulating layer 40 and one sacrificial layer 42) at the surface of the exposed regions 90b-90d of the multilayer body 100 is etched and removed as shown in FIG. 88 by RIE technique using the mask layer 80 remaining in the region 90a as a mask.

One stacked film (one insulating layer 40 and one sacrificial layer 42) at the surface of the regions 90c-90d and the newly exposed region 90b is removed. In the regions 90c-90d, one stacked film (one insulating layer 40 and one sacrificial layer 42) was already removed in the previous step. Thus, the number of stairs is increased.

The steps described above are repeated a plurality of cycles. Thus, the sacrificial layers 42 are processed into a staircase pattern along the X-direction.

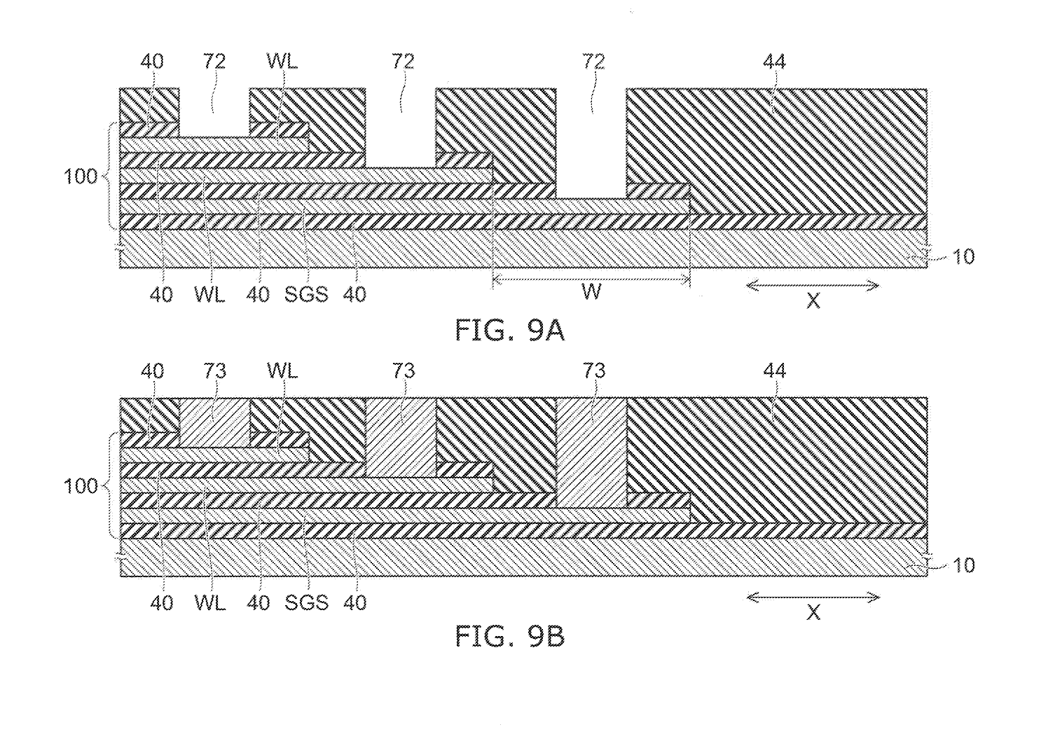

After forming a staircase part in the multilayer body 100, an interlayer insulating film 44 is formed on the staircase part as shown in FIG. 9A. The interlayer insulating film 44 covers the staircase part.

As described later, the sacrificial layers 42 are replaced by conductive layers constituting an electrode layer WL, a drain side select gate SGD, and a source side select gate SGS. FIGS. 9A and 9B show a staircase structure of a source side select gate SGS and two electrode layers WL from the bottom.

Then, a contact hole 72 is formed. The contact hole 72 penetrates through the interlayer insulating film 44 and the insulating layer 40 of each stair part. The contact holes 72 reach the electrode layer WL, the drain side select gate SGD, and the source side select gate SGS of the respective stair parts.

A conductive film is formed in the contact hole 72. A contact via (contact plug) 73 is formed as shown in FIGS. 9B and 3.

According to the embodiment described above, a mask layer 80 having a multistage staircase structure can be formed by one time of lithography for forming apertures 81a in the first film 81. The staircase structure of the mask layer 80 can be transferred to the multilayer body 100 by etch-back of the mask layer 80 and etching of the exposed region of the multilayer body 100. The embodiment eliminates the step of slimming the mask layer. This enables a significant reduction of cost.

Furthermore, the staircase width (X-direction width) of one stair depends on the patterning accuracy of the first film 81. Thus, the staircase width W can be controlled with very high accuracy. In other words, the width W of the region to which the contact hole 72 is extended in the step shown in FIG. 9A can be controlled with high accuracy. The overall width of the staircase structure is not unnecessarily widened while ensuring a sufficient width for forming the contact hole 72.

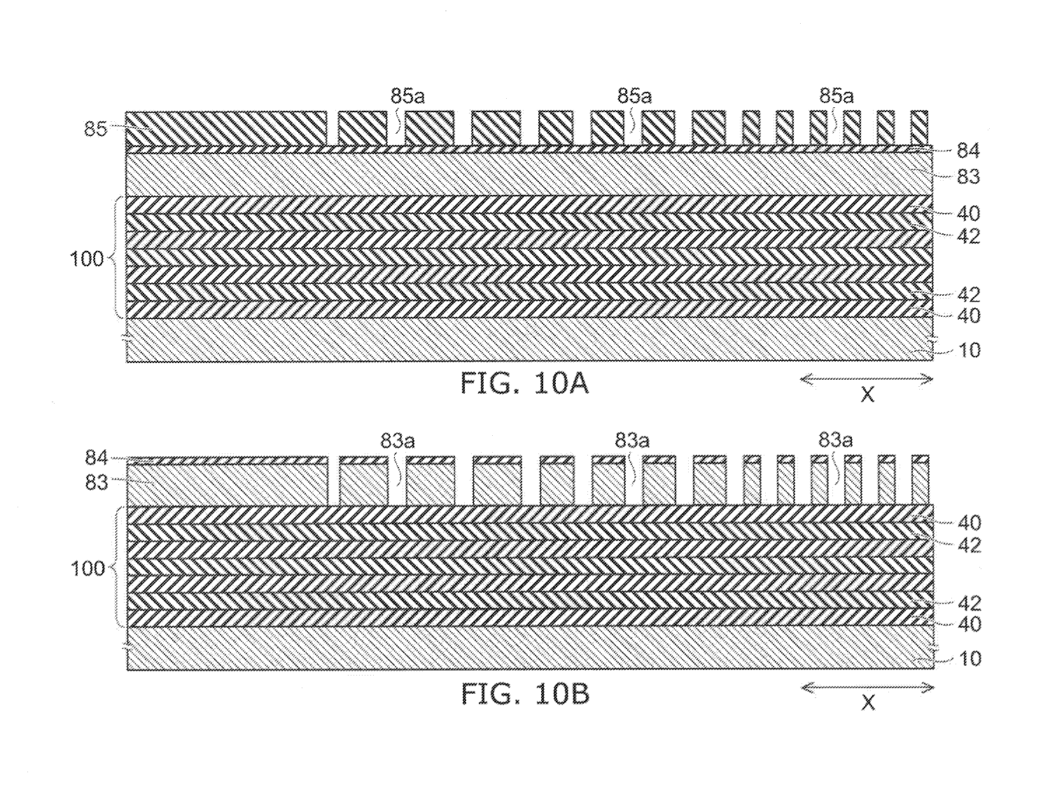

Next, FIGS. 10A to 14B are schematic sectional views showing an alternative example of the method for forming a staircase-shaped contact part of the embodiment.

Like FIGS. 4A to 9B, FIGS. 10A to 14B are also schematic sectional views of the region in which the staircase-shaped contact part shown in FIG. 3 is formed. The X-direction shown in FIGS. 10A to 14B corresponds to the X-direction shown in FIG. 3.

As shown in FIG. 10A, a first film 83 is formed on the multilayer body 100. The first film 83 is a non-photosensitive organic film. The first film 83 is formed by e.g. coating technique.

An intermediate film 84 is formed on the first film 83. A photosensitive resist film 85 is formed on the Intermediate film 84. The intermediate film 84 is a spin-on-glass (SOG) film made of a material different from the first film 83 and the resist film 85. The intermediate film 84 is composed primarily of e.g. silicon oxide.

The resist film 85 is patterned by light exposure and development on the resist film 85. As shown in FIG. 10A, a plurality of apertures 85a are formed in the resist film 85. The aperture 85a is a hole. Alternatively, the aperture 85a is a slit extending in the direction traversing the page (Y-direction in FIG. 1).

The intermediate film 84 is processed by e.g. RIE technique using the resist film 85 having the aperture 85a as a mask. Furthermore, the first film 83 is processed by RIE technique using the resist film 85 and the intermediate film 84 as a mask. Thus, the aperture 85a formed in the resist film 85 is transferred to the first film 83.

As shown in FIG. 10B, a plurality of apertures 83a are formed in the first film 83. The aperture 83a is a hole. Alternatively, the aperture 83a is a slit extending in the direction traversing the page (Y-direction in FIG. 1). The bottom of the aperture 83a reaches the upper surface of the multilayer body 100. Then, the intermediate film 84 is removed.

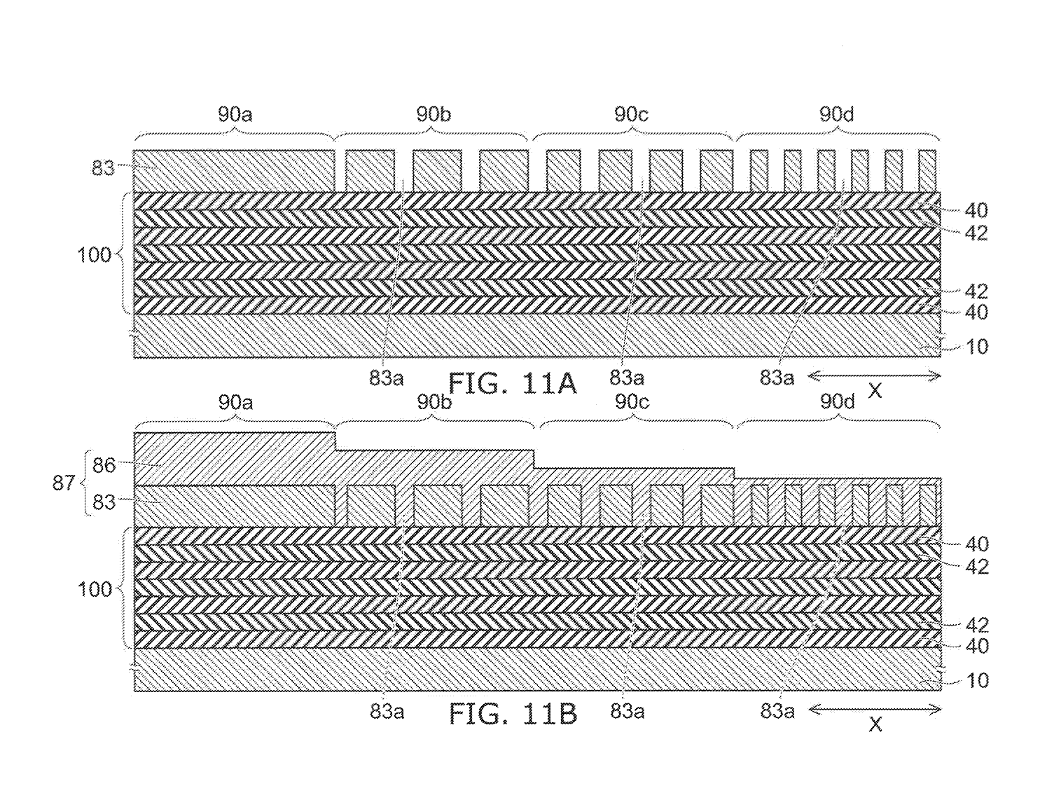

Like the first film 81 of the above embodiment, the first film 83 includes a plurality of regions 90a-90d as shown in FIG. 11A. The plurality of regions 90a-90d are arranged along the X-direction. The X-direction widths of the plurality of regions 90a-90d are generally equal. The Y-direction widths of the plurality of regions 90a-90d are generally equal. That is, the areas of the plurality of regions 90a-90d are generally equal.

The plurality of regions 90a-90d are different in aperture ratio. For instance, no aperture is formed in the region 90a. Thus, the aperture ratio of the region 90a is 0%. For instance, the aperture ratio of the region 90b is 10%. The aperture ratio of the region 90c is 30%. The aperture ratio of the region 90d is 50%.

The plurality of regions 90a-90d are arranged along the X-direction in the increasing order of aperture ratio from the region 90a of the lowest aperture ratio toward the region 90d of the highest aperture ratio.

Subsequently, the steps are performed as in the above embodiment.

As shown in FIG. 11B, a second film 86 is formed on the first film 83. The second film 86 is formed also in the aperture 83a. The second film 86 is a non-photosensitive organic film. The second film 86 is supplied onto the first film 83 and into the aperture 83a in a liquid state having fluidity. Then, the second film 86 is thermally cured. The second film 86 is cured by heat treatment below the heatproof temperature of the first film 83.

The second film 86 is applied uniformly onto the first film 83. The film thickness (height) of the first film 83 is generally equal over the plurality of regions 90a-90d. Thus, the total amount (total volume) of the second film 86 formed in the aperture 83a is different among the regions 90a-90d depending on the difference in the aperture ratio of the first film 83. This causes difference in the thickness (height) of the second film 86 on the first film 83 among the regions 90a-90d.

The thickness of the second film 86 on the first film 83 in the region 90a of the lowest aperture ratio is thicker than the thickness of the second film 86 on the first film 83 in the region 90b having higher aperture ratio than the region 90a.

The thickness of the second film 86 on the first film 83 in the region 90c having higher aperture ratio than the region 90b is thinner than the thickness of the second film 86 on the first film 83 in the region 90b.

The thickness of the second film 86 on the first film 83 in the region 90d having higher aperture ratio than the region 90c is thinner than the thickness of the second film 86 on the first film 83 in the region 90c.

The thickness of the second film 86 on the first film 83 is thinned stepwise along the X-direction from the region 90a of the lowest aperture ratio toward the region 90d of the highest aperture ratio.

The first film 83 and the second film 86 are made of the same organic film. The material thereof is different from the sacrificial layer (silicon nitride film) 42 and the insulating layer (silicon oxide film) 40 of the multilayer body 100. The first film 83 and the second film 86 form a mask layer 87 for processing the multilayer body 100 into a staircase pattern. The mask layer 87 has etching selectivity with respect to the multilayer body 100.

The total thickness of the mask layer 87 is thicker in the region having a lower aperture ratio of the first film 83. The thickness of the mask layer 87 is thinned stepwise along the X-direction from the region 90a of the lowest aperture ratio toward the region 90d of the highest aperture ratio. Thus, the upper surface of the mask layer 87 is formed in a staircase pattern along the X-direction.

Next, the multilevel upper surface of the mask layer 87 is etched back and set back in the thickness direction of the mask layer 87. For instance, the mask layer 87 made of an organic film is etched back by RIE technique using an oxygen-containing gas. At the time of this etch-back, the etching rate of the first film 83 is generally equal to the etching rate of the second film 86. Thus, the setback amount of the first film 83 is generally equal to the setback amount of the second film 86. Accordingly, the multilevel upper surface is reflected also on the upper surface of the remaining mask layer 87.

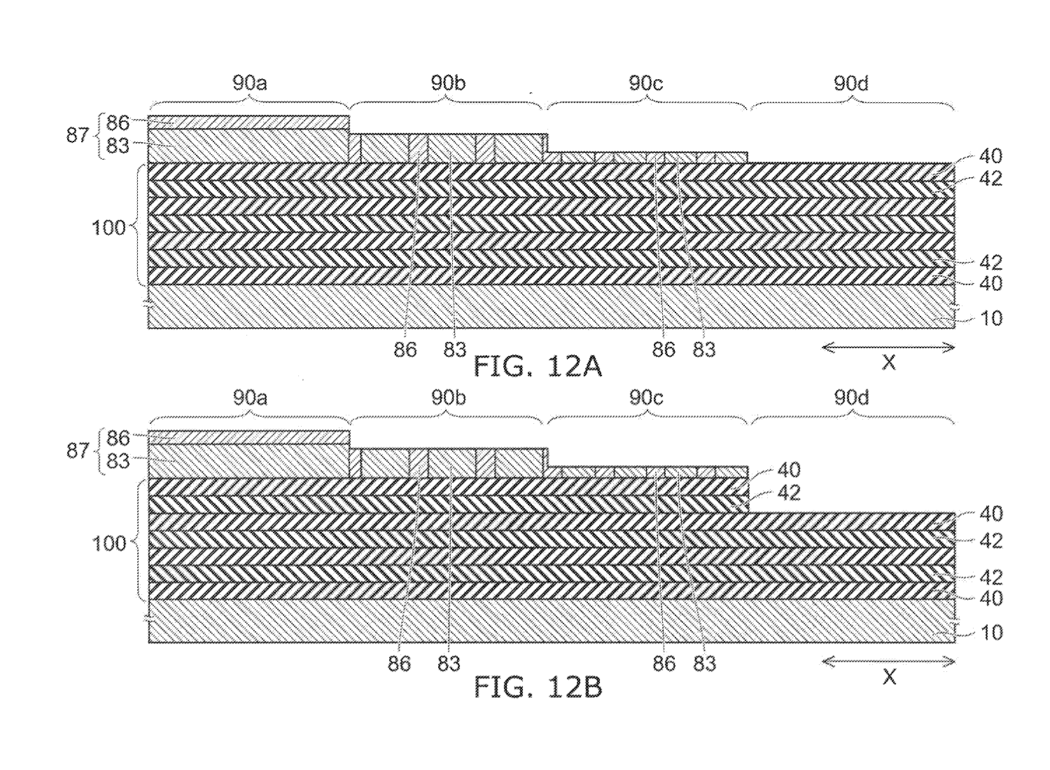

The mask layer 87 is etched back until the thinnest portion of the mask layer 87 (the mask layer 87 in the region 90d) disappears. As shown in FIG. 12A, part of the multilayer body 100 is exposed by disappearance of the mask layer 87 in the region 90d. The thickness of the mask layer 87 in the other regions 90a-90c Is made thinner than the thickness before etch-back shown in FIG. 11B.

In this state, the exposed region 90d of the multilayer body 100 is etched in the stacking direction by RIE technique using e.g. a fluorocarbon-based gas.

One stacked film (one insulating layer 40 and one sacrificial layer 42) at the surface of the exposed region 90d of the multilayer body 100 is etched and removed as shown in FIG. 12B.

By removal of the one stacked film, as shown in FIG. 12B, a step difference is formed in the multilayer body 100 between the surface covered with the mask layer 87 and the exposed surface.

Subsequently, the step of etching back the remaining mask layer 87 to eliminate the thinnest portion and the step of etching one stacked film in the exposed region of the multilayer body 100 are repeated a plurality of times.

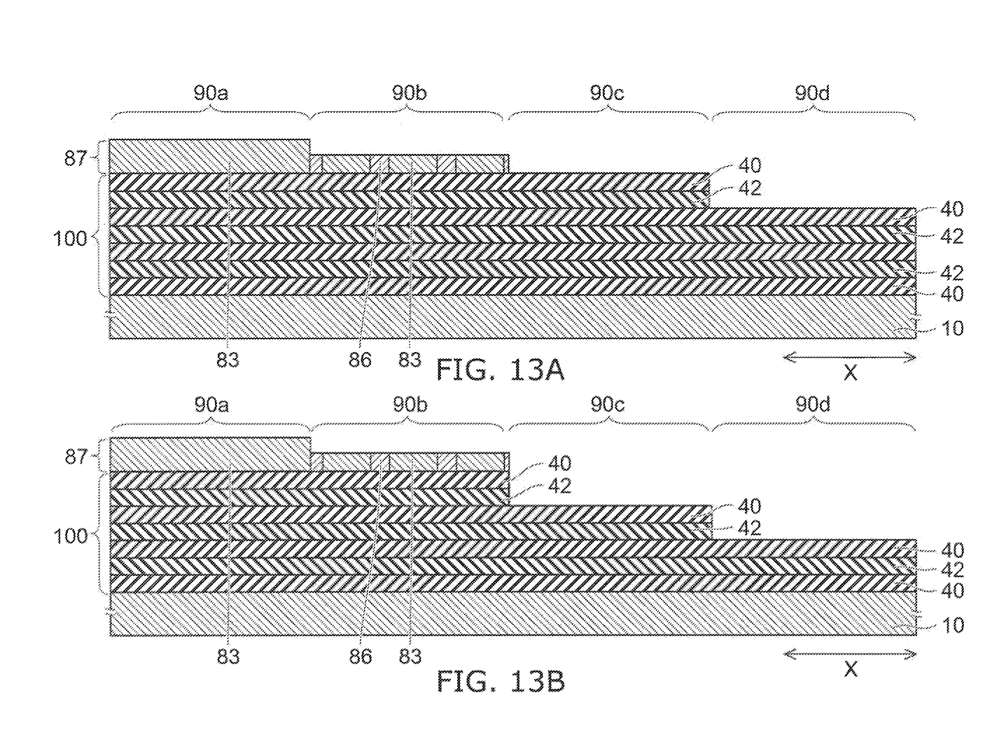

More specifically, the multilevel upper surface of the remaining mask layer 87 in FIG. 12B is etched back. Thus, the mask layer 87 is set back in the thickness direction. The thinnest portion of the remaining mask layer 87 (the mask layer 87 in the region 90c) disappears by this etch-back. Thus, the multilayer body 100 in the region 90c is exposed as shown in FIG. 13A.

Then, one stacked film (one insulating layer 40 and one sacrificial layer 42) at the surface of the exposed regions 90c-90d of the multilayer body 100 is etched and removed as shown in FIG. 13B by RIE technique using the mask layer 87 remaining in the regions 90a-90b as a mask.

One stacked film (one insulating layer 40 and one sacrificial layer 42) at the surface of the region 90d and the newly exposed region 90c is removed. In the region 90d, one stacked film (one insulating layer 40 and one sacrificial layer 42) was already removed in the previous step. Thus, the number of stairs is increased.

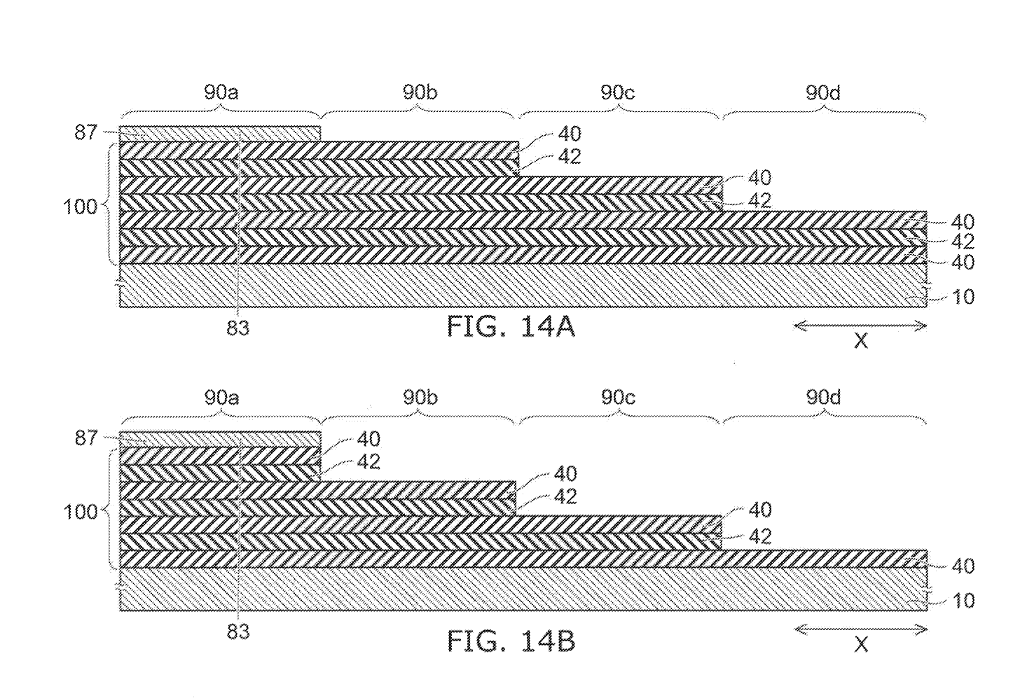

Subsequently, likewise, the multilevel upper surface of the remaining mask layer 87 in FIG. 13B is etched back. Thus, the mask layer 87 is set back in the thickness direction. The thinnest portion of the remaining mask layer 87 (the mask layer 87 in the region 90b) disappears by this etch-back. Thus, the multilayer body 100 in the region 90b is exposed as shown in FIG. 14A.

Then, one stacked film (one insulating layer 40 and one sacrificial layer 42) at the surface of the exposed regions 90b-90d of the multilayer body 100 is etched and removed as shown in FIG. 14B by RIE technique using the mask layer 87 remaining in the region 90a as a mask.

One stacked film (one insulating layer 40 and one sacrificial layer 42) at the surface of the regions 90c-90d and the newly exposed region 90b is removed. In the regions 90c-90d, one stacked film (one insulating layer 40 and one sacrificial layer 42) was already removed in the previous step. Thus, the number of stairs is increased.

The steps described above are repeated a plurality of cycles. Thus, the sacrificial layers 42 are processed into a staircase pattern along the X-direction.

Also in the embodiment shown in FIGS. 10A to 14B, a mask layer 87 having a multistage staircase structure can be formed by one time of lithography for forming apertures 83a in the first film 83. The staircase structure of the mask layer 87 can be transferred to the multilayer body 100 by etch-back of the mask layer 87 and etching of the exposed region of the multilayer body 100. This embodiment also eliminates the step of slimming the mask layer. This enables a significant reduction of cost.

Furthermore, the staircase width (X-direction width) of one stair depends on the patterning accuracy of the first film 83. Thus, the staircase width W can be controlled with very high accuracy. The overall width of the staircase structure is not unnecessarily widened while ensuring a sufficient width for forming the contact hole 72.

Depending on the material of the multilayer body 100, the resist film may be unsuitable to be part of the mark layer (first film).

However, according to the embodiment shown in FIGS. 10A to 14B, the resist film is not formed as a first film on the multilayer body 100. This allows a high degree of freedom of material selection for the first film 83 appropriate for the material of the multilayer body 100.

The first film 83 is also desired to have heat resistance at the time of thermally curing the second film 86 after supplying the second film 86. Also in this regard, it is desirable to increase the degree of freedom of material selection for the first film 83.

Thickening the resist film is limited in view of the restriction on lithography. However, there is no such thickness limitation on the first film 83, which is not subjected to light exposure. This makes it possible to form a first film 83 thicker than the resist film. A thick first film 83 thickens the total thickness of the mask layer 87. A thick mask layer 87 facilitates changing the thickness in a larger number of stages, i.e., forming staircase steps in a large number of stairs. Thus, a larger number of stairs can be transferred to the multilayer body 100 by the mask layer 87 formed once.

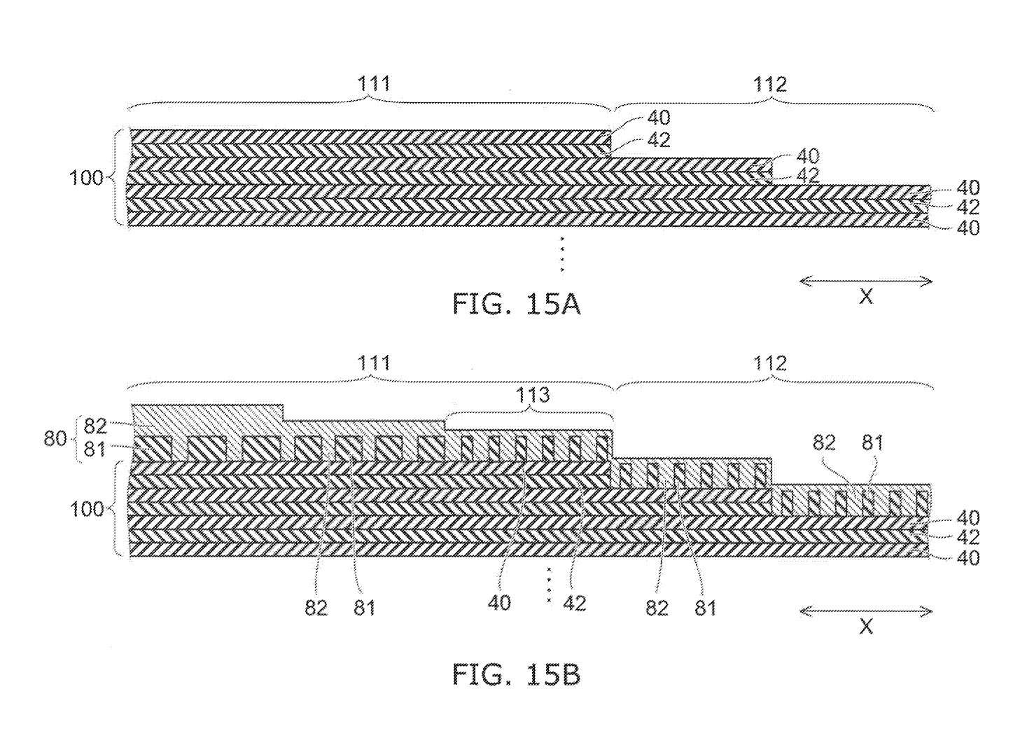

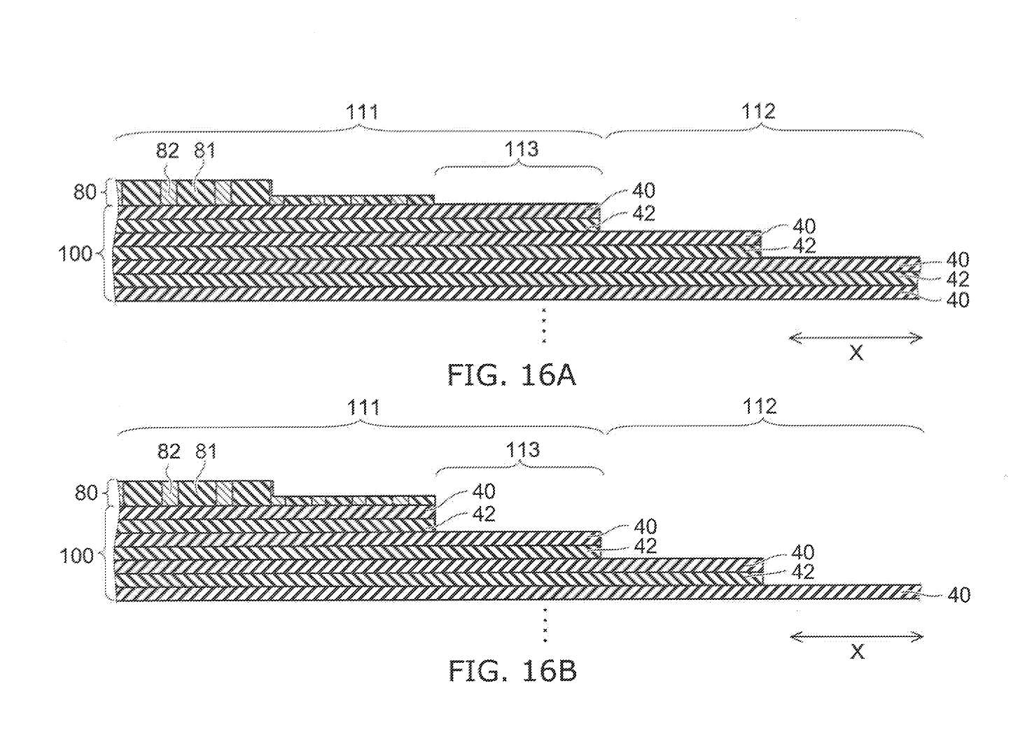

Next, FIGS. 15A to 16B are schematic sectional views showing a further alternative example of the method for forming a staircase-shaped contact part of the embodiment.

With the increase of the number of stairs, the mask layer itself or the staircase formed in the mask layer may disappear before completing processing all the first layers 42 into a staircase pattern while etch-back of the mask layer and etching of the multilayer body 100 are repeated a plurality of times.

FIG. 15A shows the state in which the staircase processing on the multilayer body 100 has proceeded halfway by the aforementioned process. In the state shown in FIG. 15A, the mask layer has disappeared before completing the staircase processing for a desired number of stairs. Alternatively, the staircase structure of the mask layer has disappeared, and the mask layer remaining with a uniform thickness has been removed.

By the aforementioned process, the exposed region of the multilayer body 100 is expanded from right to left in the X-direction in FIG. 15A. This removes one stacked film (one insulating layer 40 and one sacrificial layer 42) at the surface to form a staircase-shaped first region 112. FIG. 15A shows the state in which the mask layer itself or the staircase structure of the mask layer has disappeared at this point. A second region 111 is located on the immediate left side of the first region 112 in the X-direction. The second region 111 is covered with the mask layer and not etched in this process.

Then, as shown in FIG. 15B, a mask layer 80 having a multilevel upper surface is formed again on the first region 112 and the second region 111. In the first region 112, the multilayer body 100 has already been etched. In the second region 111, the multilayer body 100 has not been etched yet. The mask layer 80 is formed as in the aforementioned steps of FIGS. 4B to 5B. Alternatively, a mask layer 87 may be formed as in the steps of FIGS. 10A to 11B.

The aperture ratio of the first film 81 in the end part region 113 of the second region 111 neighboring the first region 112 is generally equal to the aperture ratio of the first film 81 in the first region 112. Thus, the thickness of the mask layer 80 in the end part region 113 of the second region 111 is generally equal to the thickness of the mask layer 80 in the first region 112.

The aperture ratio of the first film 81 in the second region 111 increases stepwise toward the end part region 113. Thus, the thickness of the mask layer 80 in the second region 111 is thinned toward the end part region 113.

The film thickness of the first film 81 is generally equal over the first region 112 and the second region 111.

Then, the mask layer 80 is etched back and set back in the thickness direction. Thus, the mask layer 80 in the end part region 113 of the second region 111 and the mask layer 80 in the first region 112 are eliminated. As shown in FIG. 16A, the multilayer body 100 is exposed in the end part region 113 of the second region 111 and the first region 112.

Then, one stacked film (one insulating layer 40 and one sacrificial layer 42) at the exposed surface of the end part region 113 of the second region 111 and the first region 112 is etched in the stacking direction. Thus, as shown in FIG. 16B, a staircase continued from the staircase in the first region 112 is formed in the end part region 113 of the second region 111.

Subsequently, etch-back of the mask layer 80 remaining on the multilayer body 100 and etching of one stacked film (one insulating layer 40 and one sacrificial layer 42) at the surface of the exposed region of the multilayer body 100 are repeated as in the above embodiment.

Also for the mask layer 80 thus formed, the aforementioned steps of FIGS. 15B to 16B are repeated in the case where the mask layer 80 has disappeared before completing the staircase processing for a desired number of stairs.

For a larger number of stairs, the step of re-forming the mask layer may be increased. However, there is no slimming step of the mask layer. Thus, it is possible to easily form a staircase structure in which the staircase width is controlled with high accuracy.

Next, a method for forming the memory cell array 1 is described with reference to FIGS. 17A to 23.

For instance, the aforementioned staircase part is formed in the multilayer body 100. Furthermore, an interlayer insulating film 44 is formed on the staircase part. Then, as shown in FIG. 17A, a plurality of memory holes 71 are formed in the region of multilayer body 100 in which the memory cell array 1 is to be formed. The memory holes 71 are formed by RIE technique using a mask, not shown. The memory hole 71 penetrates through the multilayer body 100 to the substrate 10.

As shown in FIG. 17B, a memory film 30 is formed on the Inner wall (sidewall and bottom part) of the memory hole 71. A cover film 20a is formed inside the memory film 30.

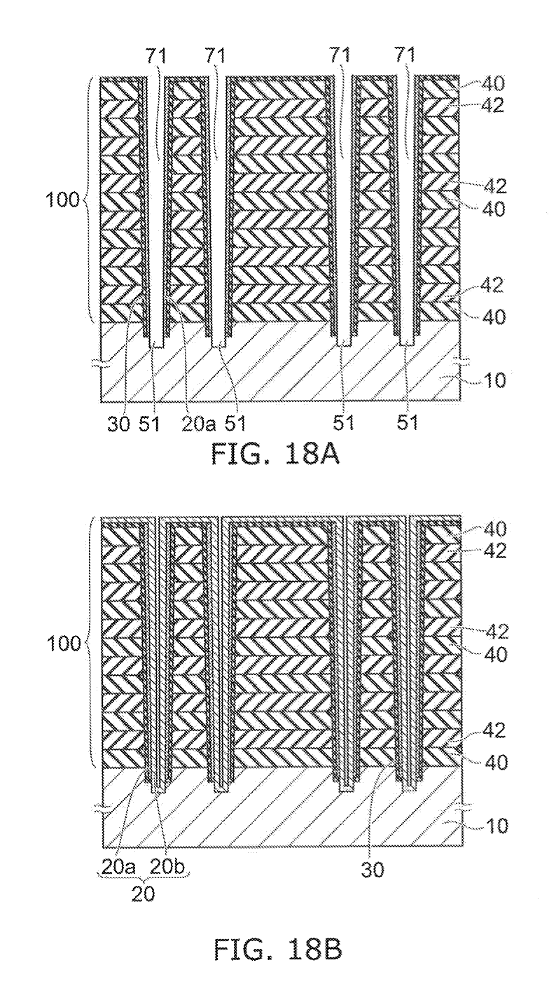

The cover film 20a and the memory film 30 formed on the bottom part of the memory hole 71 are removed by RIE technique. Thus, as shown in FIG. 18A, a hole 51 is formed in the bottom part of the memory hole 71. The substrate 10 forms the side surface and the bottom surface of the hole 51.

At the time of this RIE, the memory film 30 formed on the sidewall of the memory hole 71 is covered with and protected by the cover film 20a. Thus, the memory film 30 formed on the sidewall of the memory hole 71 is not damaged by RIE.

Next, as shown in FIG. 18B, a semiconductor film 20b Is formed in the hole 51 and inside the cover film 20a. The cover film 20a and the semiconductor film 20b are formed as e.g. an amorphous silicon film, and then turned to a polycrystalline silicon film by annealing treatment. The cover film 20a in conjunction with the semiconductor film 20b constitutes the aforementioned semiconductor film 20.

The semiconductor film 20 is electrically connected to the substrate 10 through the semiconductor film 20b formed in the hole 51.

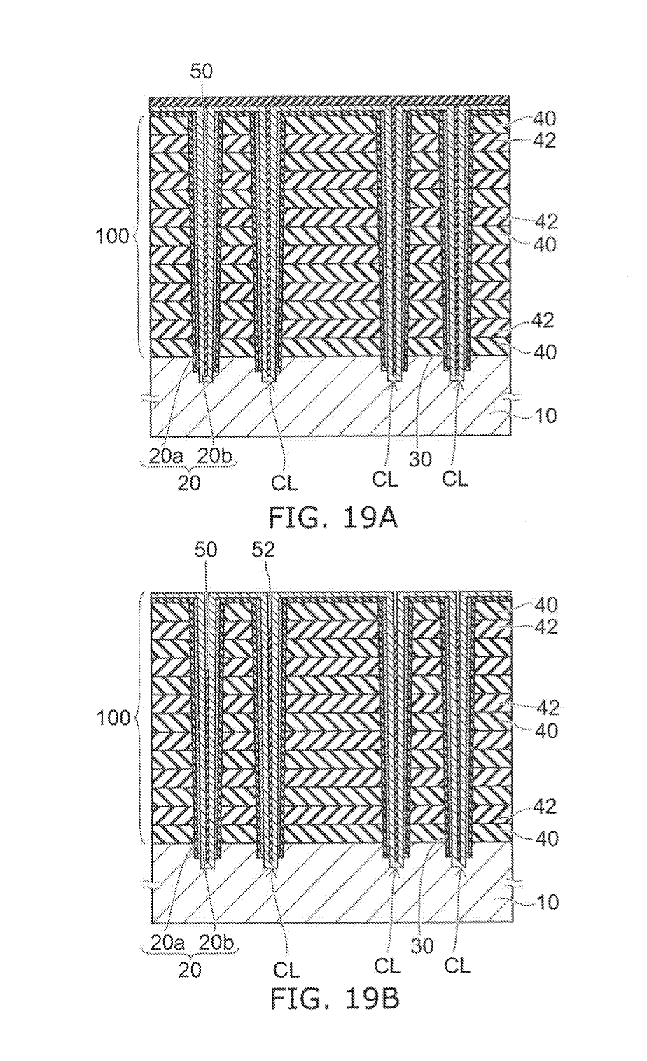

As shown in FIG. 19A, a core insulating film 50 is formed inside the semiconductor film 20b. Thus, a columnar part CL is formed. The upper part of the core insulating film 50 is etched back. Thus, as shown in FIG. 19B, a void 52 is formed in the upper part of the columnar part CL.

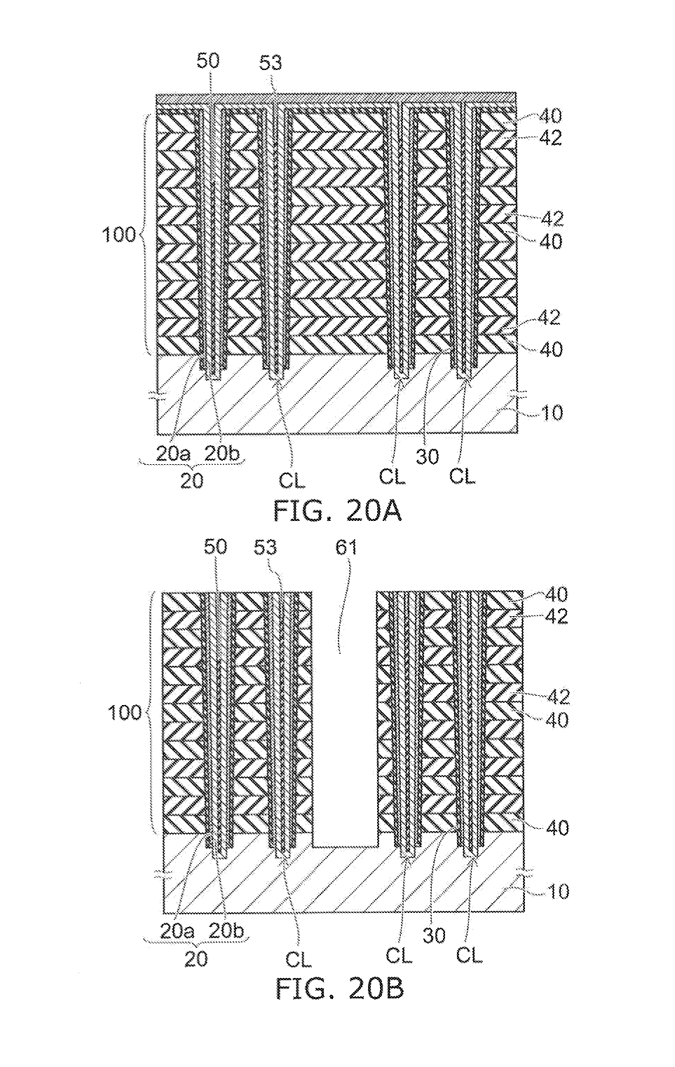

As shown in FIG. 20A, a semiconductor film 53 is buried in the void 52. The semiconductor film 53 is e.g. a doped silicon film. The semiconductor film 53 has higher impurity concentration than the semiconductor film 20 made of a non-doped silicon film.

In a typical memory of the charge injection type, electrons written in the charge storage layer such as a floating gate are extracted by raising the substrate potential to erase data. An alternative erasure method is to boost the channel potential of the memory cell by utilizing a gate induced drain leakage (GIDL) current produced in the channel at the upper end of the drain side select gate.

In this embodiment, a high electric field is applied to the semiconductor film 53 of high impurity concentration formed near the upper end part of the drain side select gate SGD. Thus, holes are generated in the semiconductor film 53. The holes are supplied to the semiconductor film 20 to raise the channel potential. The potential of the electrode layer WL is set to e.g. ground potential (0 V). Thus, the holes are injected into the charge storage film 32 by the potential difference between the semiconductor film 20 and the electrode layer WL. Accordingly, the operation of erasing data is performed.

The memory film 30, the semiconductor film 20, and the semiconductor film 53 deposited on the upper surface of the multilayer body 100 are removed after the semiconductor film 53 is buried in the void 52.

Next, as shown in FIG. 20B, a slit 61 is formed in the multilayer body 100 by RIE technique using a mask, not shown. The slit 61 penetrates through the multilayer body 100 to the substrate 10.

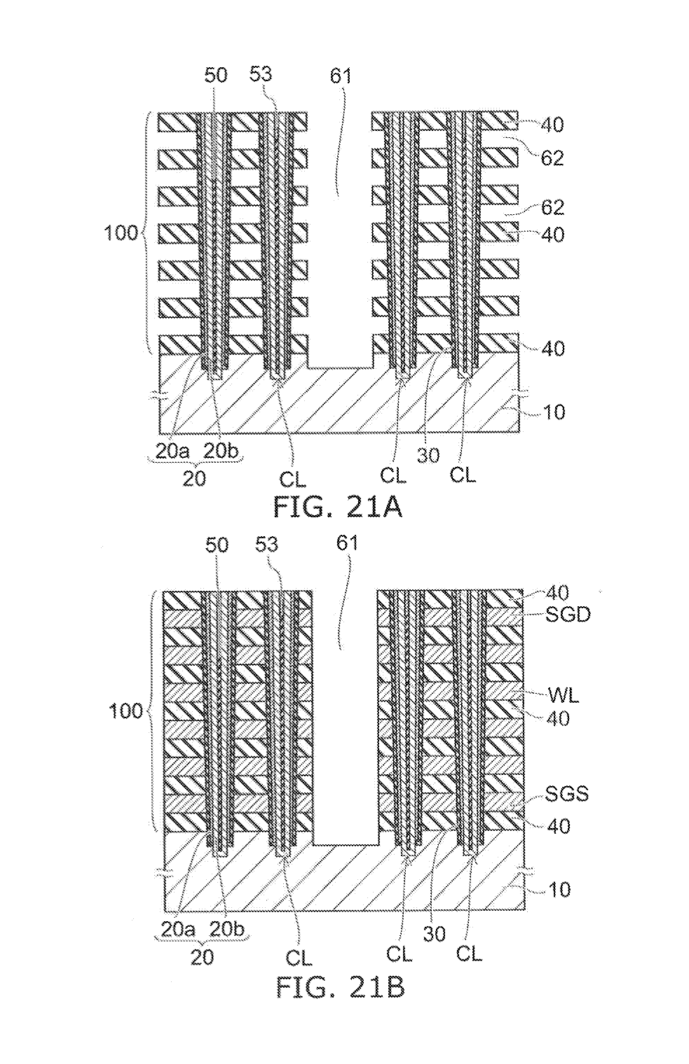

The sacrificial layer 42 is removed by etching through the slit 61. By the removal of the sacrificial layer 42, a space 62 is formed between the insulating layers 40 as shown in FIG. 21A.

As shown in FIG. 21B, conductive layers are formed in the space 62 through the slit 61. The conductive layers constitute an electrode layer WL, a drain side select gate SGD, and a source side select gate SGS.

The drain side select gate SGD is formed in the space 62 of the uppermost layer. The source side select gate SGS is formed in the space 62 of the lowermost layer. The electrode layer WL is formed in the space 62 between the uppermost layer and the lowermost layer.

The electrode layer WL, the drain side select gate SGD, and the source side select gate SGS are metal layers, and include e.g. tungsten.

Also in the staircase part, the sacrificial layers 42 are replaced by an electrode layer WL, a drain side select gate SGD, and a source side select gate SGS.

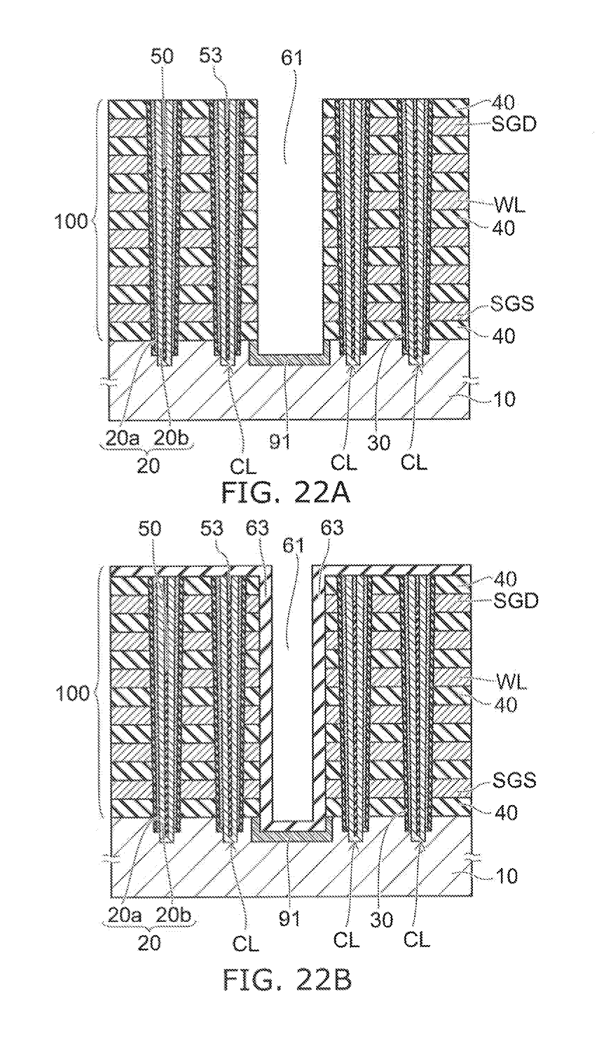

Next, impurity is implanted into the surface of the substrate 10 at the bottom of the slit 61. The implanted impurity is diffused by the subsequent heat treatment. Thus, as shown in FIG. 22A, a contact region 91 is formed in the surface of the substrate 10 at the bottom of the slit 61.

Next, as shown in FIG. 228, an Insulating film 63 is formed on the inner wall (sidewall and bottom part) of the slit 61. The insulating film 63 formed on the bottom part of the slit 61 is removed by RIE technique.

Then, as shown in FIG. 23, a source layer SL is buried in the slit 61. The lower end part of the source layer SL is connected to the substrate 10 through the contact region 91. The lower end of the semiconductor film 20 is electrically connected to the source layer SL through the substrate 10.

Then, the drain side select gate SGD is separated in the Y-direction as shown in FIG. 1. Furthermore, for instance, bit lines BL shown in FIG. 1 and upper interconnection connected to the source layer SL are formed.

In the multilayer body 100, it is also possible to form an electrode layer WL as a first layer without forming the sacrificial layer 42. In this case, there is no process of replacement from the sacrificial layer 42 to the electrode layer WL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
forming a first film on a multilayer body including two or more stacked films, one stacked film including a first layer and a second layer made of a material different from a material of the first layer, the first film including a plurality of regions different in aperture ratio and made of a material different from a material of the stacked films;
forming a mask layer by forming a second film on the first film and in apertures formed in the first film, the second film being made of a material different from the material of the stacked films, the mask layer being thicker in a region in which the aperture ratio is lower, and the mask layer having a multilevel upper surface;
eliminating a thinnest portion of the mask layer to expose part of the multilayer body by etching back the multilevel upper surface in a thickness direction of the mask layer; and
etching one stacked film on a surface side of an exposed region of the multilayer body in a stacking direction.

2. The method according to claim 1, wherein the eliminating the thinnest portion of the mask layer and the etching the one stacked film in the exposed region of the multilayer body are repeated a plurality of times, and the first layers included in the stacked films are processed into a staircase pattern.

3. The method according to claim 1, wherein
the plurality of regions of the first film are arranged along a first direction in an increasing order of the aperture ratio from a region of a lowest aperture ratio toward a region of a highest aperture ratio, and
the mask layer is thinned stepwise along the first direction from the region of the lowest aperture ratio toward the region of the highest aperture ratio.

4. The method according to claim 1, wherein the second film with fluidity is supplied onto the first film and into the apertures, and then cured.

5. The method according to claim 4, wherein the second film is thermally cured below heatproof temperature of the first film.

6. The method according to claim 1, wherein
the first film is a photosensitive resist film, and
the apertures are formed in the resist film by light exposure and development on the resist film.

7. The method according to claim 6, wherein the second film is a non-photosensitive organic film.

8. The method according to claim 1, wherein the apertures in the first film are formed by:
forming an intermediate film on the first film formed on the multilayer body, the Intermediate film being made of a material different from the material of the first film;
forming a resist film on the intermediate film;
forming apertures in the resist film by light exposure and development on the resist film; and
transferring the apertures formed in the resist film to the intermediate film and the first film.

9. The method according to claim 8, wherein the first film is an organic film, and the Intermediate film is a film composed primarily of silicon oxide.

10. The method according to claim 2, further comprising:
forming an Interlayer insulating film covering the first layers processed into the staircase pattern;
forming holes penetrating through the interlayer insulating film and reaching a height of respective upper surfaces of the first layers; and
forming a conductive film in the holes.

11. The method according to claim 2, wherein the first layers are replaced by conductive layers after the first layers are processed into the staircase pattern.

12. The method according to claim 11, wherein the first layer is a silicon nitride film, the second layer is a silicon oxide film, and the conductive layers are metal layers.

13. The method according to claim 1, further comprising:
forming a hole in the multilayer body, the hole extending in the stacking direction;
forming a film including a charge storage film on a sidewall of the hole; and
forming a semiconductor film on a sidewall of the film including the charge storage film.

14. The method according to claim 1, wherein a film thickness of the first film is generally equal over the plurality of regions.

15. The method according to claim 1, wherein setback amounts of the first film and the second film are generally equal when the mask layer is etched back.

16. The method according to claim 1, wherein the first film and the second film are films made of a homogeneous material.

17. A method for manufacturing a semiconductor device, comprising:
forming a first film on a multilayer body including two or more stacked films, one stacked film including a first layer and a second layer made of a material different from a material of the first layer, the first film including a plurality of regions different in aperture ratio and made of a material different from a material of the stacked films;
forming a mask layer by forming a second film on the first film and in apertures formed in the first film, the second film being made of a material different from the material of the stacked films, the mask layer being thicker in a region in which the aperture ratio is lower, and the mask layer having a multilevel upper surface;
eliminating a thinnest portion of the mask layer to expose part of the multilayer body by etching back the multilevel upper surface in a thickness direction of the mask layer;
etching one stacked film on a surface side of an exposed region of the multilayer body in a stacking direction;
forming the mask layer having the multilevel upper surface again on a first region and a second region, the multilayer body having been etched in a staircase pattern in the first region, the multilayer body having not been etched in the second region;
eliminating the mask layer in an end part region of the second region neighboring the first region and the mask layer in the first region to expose part of the multilayer body in the end part region of the second region and the first region by etching back the mask layer in the thickness direction; and
etching one stacked film on a surface side of the exposed end part region of the second region and on a surface side of the exposed first region in the stacking direction.

18. The method according to claim 17, wherein in forming the mask layer again, the aperture ratio of the first film in the end part region of the second region and the aperture ratio of the first film in the first region are generally equal.

19. The method according to claim 17, wherein a thickness of the mask layer in the end part region of the second region and a thickness of the mask layer in the first region are generally equal.

20. The method according to claim 17, wherein
the aperture ratio of the first film in the second region is increased stepwise toward the end part region, and
a thickness of the mask layer in the second region is thinned stepwise toward the end part region.
